(19) United States
(12) Patent Application Publication
(10) Pub. No.: US 2025/0364208 A1
(43) Pub. Date: Nov. 27, 2025

(54) BACKGROUND WAVEFORM ACQUISITION METHOD, MARK POSITION DETECTION METHOD, ELECTRON BEAM WRITING METHOD, AND ELECTRON BEAM WRITING APPARATUS

(71) Applicant: NuFlare Technology, Inc., Yokohama-shi (JP)

(72) Inventors: Kaoru TSURUTA, Yokohama-shi (JP); Hiroshi SATO, Yokohama-shi (JP); Tsubasa NANAO, Yokohama-shi (JP)

(73) Assignee: NuFlare Technology, Inc., Yokohama-shi (JP)

(21) Appl. No.: 19/202,002

(22) Filed: May 8, 2025

(30) Foreign Application Priority Data
May 24, 2024 (JP) 2024-084772

(51) Int. Cl. H01J 37/304; H01J 37/317

(52) U.S. Cl. CPC H01J 37/3045; H01J 37/3177; H01J 2237/0437; H01J 2237/24578; H01J 2237/30483

(57) ABSTRACT

According to one aspect of the present invention, a background waveform acquisition method includes scanning a target object with an electron beam, at a plurality of regions which are in a vicinity of a line pattern on the target object where a mark using the line pattern is formed, and are arranged in a direction not parallel to an extending direction of the line pattern, and determining a waveform of a background which is not the mark, in a plurality of measured waveforms measured by the scanning at the plurality of regions, and outputting the waveform of the background.

### CROSS-REFERENCE TO RELATED APPLICATION

This application is based upon and claims the benefit of priority from prior Japanese Patent Application No. 2024-084772 filed on May 24, 2024 in Japan, the entire contents of which are incorporated herein by reference.

### BACKGROUND OF THE INVENTION

### Field of the Invention

Embodiments of the present invention relate to a background waveform acquisition method, a mark position detection method, an electron beam writing method, and an electron beam writing apparatus. For example, embodiments relate to a method for measuring the position of a mark formed on the substrate serving as a writing target.

### Description of Related Art

The lithography technique which advances miniaturization of semiconductor devices is extremely important as a unique process in which patterns are formed in semiconductor manufacturing. In recent years, with high integration of LSI, the line width (critical dimension) necessary for semiconductor device circuits is decreasing year by year. The electron beam writing technique, which intrinsically has excellent resolution, is used for writing or “drawing” patterns on a wafer and the like with electron beams.

For example, as a known example of employing the electron beam writing technique, there is a writing apparatus using multiple beams. Since writing with multiple beams can apply a lot of beams at a time, the writing throughput can be greatly increased compared to writing with a single electron beam. For example, a writing apparatus employing the multiple beam system forms multiple beams by letting an electron beam emitted from an electron gun pass through a mask having a plurality of holes, performs blanking control for each beam, reduces each unblocked beam to generate a reduced mask image by an optical system, and deflects, by a deflector, a reduced beam to be applied to a desired position on a target object or “sample”.

With regard to electron beam writing including multiple beam writing, when a writing target substrate is arranged on the stage, a mark (alignment mark) formed on the substrate is detected with an electron beam. Then, based on a detected alignment mark, alignment of a writing region is performed.

Alignment marks of recent date are formed with a finer line width (critical dimension) compared with conventional alignment marks. Therefore, when a mark is irradiated with an electron beam, the electron yield is too small to achieve good contrast. As a result, there is a problem that the SN ratio is low, and therefore, alignment marks on the target object cannot be found easily. To cope with this problem, it is examined to increase the dose (irradiation amount) of an electron beam in order to obtain contrast. However, if this method is employed, a high-dose electron beam is applied to resist in a large area, resulting in a problem that the resist is scattered to contaminate the inside of the chamber.

Then, in order to obtain contrast, a technology is proposed in which background components acquired by scanning a position with no mark are removed from the waveform acquired by scanning a mark (e.g., refer to Japanese Patent Application Laid-open (JP-A) No. 2001-085300). However, scan waveforms tend to be affected by inclination of the substrate, etc. Therefore, it is desirable to acquire a waveform, being a background, in the vicinity of a target mark. However, when trying to acquire the waveform of a position with no mark in the vicinity of a mark, there is a possibility of acquiring the waveform of a position including a mark, due to deviation of arrangement of the substrate, etc. Accordingly, judging whether it is a background component or not is difficult.

### BRIEF SUMMARY OF THE INVENTION

According to one aspect of the present invention, a background waveform acquisition method includes

scanning a target object with an electron beam, at a plurality of regions which are in a vicinity of a line pattern on the target object where a mark using the line pattern is formed, and are arranged in a direction not parallel to an extending direction of the line pattern, and

determining a waveform of a background which is not the mark, in a plurality of measured waveforms measured by the scanning at the plurality of regions, and outputting the waveform of the background.

According to another aspect of the present invention, a mark position detection method includes

scanning a target object with an electron beam, at a plurality of regions which are in a vicinity of a line pattern on the target object where a mark using the line pattern is formed, and are arranged in a direction not parallel to an extending direction of the line pattern,

determining a waveform of a background which is not the mark, in a plurality of measured waveforms measured by the scanning at the plurality of regions,

scanning the target object with an electron beam, at a region including the line pattern,

removing the waveform of the background which has been obtained by the determining, from a measured waveform measured by the scanning the region including the line pattern, and

calculating a mark position based on the measured waveform from which the waveform of the background has been removed, and outputting the mark position.

According to yet another aspect of the present invention, an electron beam writing method includes

scanning, for each mark of a plurality of marks on a target object where the plurality of marks using line patterns are formed, the target object with an electron beam, at a plurality of regions each of which is in a vicinity of one of the line patterns, and each of which is arranged in a direction not parallel to an extending direction of the one of the line patterns,

determining, for each of the marks, a waveform of a background which is not a mark concerned, in a plurality of measured waveforms measured by the scanning at the plurality of regions,

scanning, for each of the marks, the target object with an electron beam, at a region including one of the line patterns,

removing, for each of the marks, the waveform of the background which has been obtained by the determining, from a measured waveform measured by the scanning the region including the one of the line patterns,

calculating, for each of the marks, a mark position based on the measured waveform from which the waveform of the background has been removed,

correcting a position of a pattern to be written, using calculated positions of the plurality of marks, and

writing the pattern whose position has been corrected on the target object using an electron beam.

According to yet another aspect of the present invention, an electron beam writing apparatus includes

a stage configured to place thereon a target object where a plurality of marks using line patterns are formed,

a scanning mechanism configured to scan, for each mark of the plurality of marks on the target object, the target object with an electron beam, at a plurality of regions each of which is in a vicinity of one of the line patterns, and each of which is arranged in a direction not parallel to an extending direction of the one of the line patterns,

a determination circuit configured to determine, for each of the marks, a waveform of a background which is not a mark concerned, in a plurality of measured waveforms measured by scanning at the plurality of regions,

a background waveform removal circuit configured to remove, for each of the marks, the waveform of the background which has been obtained by determination, from a measured waveform measured by scanning the target object with an electron beam at a region including one of the line patterns,

a mark position calculation circuit configured to calculate, for each of the marks, a mark position based on the measured waveform from which the waveform of the background has been removed;

a correction circuit configured to correct a position of a pattern to be written, using calculated positions of the plurality of marks, and

a writing mechanism configured to include the stage and the scanning mechanism, and to write the pattern whose position has been corrected on the target object using an electron beam.

### BRIEF DESCRIPTION OF THE DRAWINGS

FIG. 1 is an illustration showing a schematic diagram of a configuration of a writing apparatus according to a first embodiment;

FIG. 2 is a conceptual diagram showing a configuration of a shaping aperture array substrate according to the first embodiment;

FIG. 3 is a sectional view showing a configuration of a blanking aperture array mechanism according to the first embodiment;

FIG. 4 is a conceptual diagram showing an example of a writing operation according to the first embodiment;

FIG. 5 is an illustration showing an example of an irradiation region of multiple beams and a writing target pixel according to the first embodiment;

FIG. 6 is an illustration for explaining an example of a multi-beam writing operation according to the first embodiment;

FIG. 7 is an illustration showing an example of a positional relationship between a stage and a target object according to the first embodiment;

FIG. 8 is a sectional view showing an example of a configuration of an alignment mark according to the first embodiment;

FIG. 9 is a sectional view showing another example of a configuration of an alignment mark according to the first embodiment;

FIG. 10 is an illustration showing an example of a positional relationship between an “off mark” region and an alignment mark according to a comparative example of the first embodiment;

FIG. 11 is an illustration showing another example of a positional relationship between an “off mark” region and an alignment mark according to a comparative example of the first embodiment;

FIG. 12 is a flowchart showing an example of main steps of a writing method according to the first embodiment;

FIG. 13 is an illustration showing an example of a positional relationship among an alignment mark, an “on mark” region, and a plurality of “off mark” regions according to the first embodiment;

FIG. 14 is an illustration showing an example of a positional relationship between an alignment mark, and a plurality of “off mark” regions according to the first embodiment;

FIG. 15 is an illustration showing another example of a positional relationship among an alignment mark, an “on mark” region, and a plurality of “off mark” regions according to the first embodiment;

FIG. 16 is an illustration showing an example of a positional relationship between an alignment mark, and a plurality of “off mark” regions according to the first embodiment;

FIG. 17 is an illustration for explaining an example of a scanning method over the “off mark” region 12 according to the first embodiment;

FIG. 18 is an illustration for explaining another example of a scanning method over the “off mark” region 12 according to the first embodiment;

FIG. 19 is an illustration showing an example of a measured waveform A according to the first embodiment;

FIG. 20 is an illustration showing an example of a measured waveform B according to the first embodiment;

FIG. 21 is an illustration showing an example of a difference waveform (A-B) according to the first embodiment;

FIG. 22 is an illustration showing an example of a difference waveform (B-A) according to the first embodiment;

FIG. 23 is an illustration showing another example of the measured waveform A according to the first embodiment;

FIG. 24 is an illustration showing another example of the measured waveform B according to the first embodiment;

FIG. 25 is an illustration showing another example of the difference waveform (A-B) according to the first embodiment;

FIG. 26 is an illustration showing another example of the difference waveform (B-A) according to the first embodiment;

FIG. 27 is an illustration showing an example of a result of a difference waveform for each combination in the case of there being three “off mark” regions according to the first embodiment;

FIG. 28 is an illustration showing another example of a result of a difference waveform for each combination in the case of there being three “off mark” regions according to the first embodiment;

FIG. 29 is an illustration for explaining an example of a method for determining a background waveform, using a template, according to the first embodiment;

FIG. 30 is an illustration showing an example of a measured waveform whose difference waveform has a peak according to the first embodiment;

FIG. 31 is an illustration for explaining a method of shifting an “on mark” region according to the first embodiment;

FIG. 32 is an illustration showing an example of a mark position according to the first embodiment;

FIG. 33 is an illustration showing an example of a method of correcting data according to the first embodiment; and

FIG. 34 is an illustration showing an example of a positional relationship among an alignment mark, an “on mark” region, and a plurality of “off mark” regions according to a modified example of the first embodiment.

### DETAILED DESCRIPTION OF THE INVENTION

Embodiments of the present invention provide a method that can highly accurately acquire a background waveform in the vicinity of a mark by a simple methodology.

Embodiments of the present invention describe a configuration which uses an electron beam as an example of a charged particle beam. The charged particle beam is not limited to the electron beam, and other charged particle beams such as an ion beam may also be used. Embodiments below describe a configuration using multiple beams as an electron beam, but it is not limited thereto. The configuration may also use a single beam.

### First Embodiment

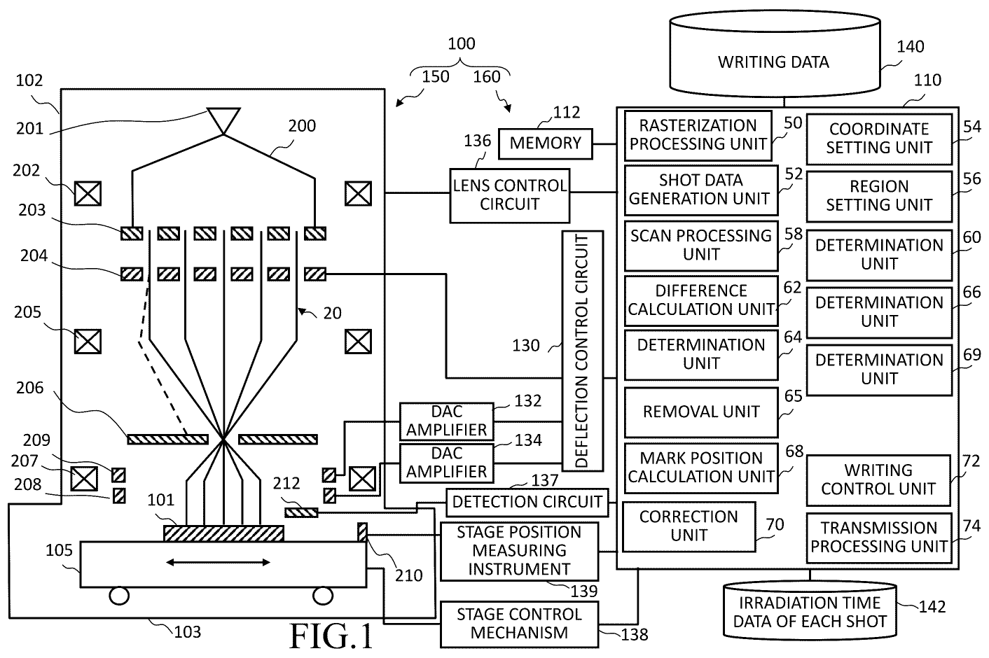

FIG. 1 is an illustration showing a schematic diagram of a configuration of a writing or “drawing” apparatus according to a first embodiment. As shown in FIG. 1, a writing apparatus 100 includes a writing mechanism 150 and a control system circuit 160. The writing apparatus 100 is an example of a multiple charged particle beam writing apparatus and an example of a multiple charged particle beam exposure apparatus. The writing mechanism 150 includes an electron optical column 102 (electron beam column) and a writing chamber 103. In the electron optical column 102, there are disposed an electron gun 201, an illumination lens 202, a shaping aperture array substrate 203, a blanking aperture array mechanism 204, a reducing lens 205, a limiting aperture substrate 206, an objective lens 207, a main deflector 208, a sub deflector 209, and a detector 212.

In the writing chamber 103, an XY stage 105 is disposed. On the XY stage 105, there is placed a target object or “sample” 101, such as a mask, serving as a writing target substrate when writing (exposure) is performed. For example, the target object 101 is an exposure mask used in fabricating semiconductor devices, or a semiconductor substrate (silicon wafer) for fabricating semiconductor devices. The target object 101 may be a mask blank on which resist has been applied and nothing has yet been written. On the XY stage 105, a mirror 210 for measuring the position of the XY stage 105 is placed.

The control system circuit 160 includes a control computer 110, a memory 112, a deflection control circuit 130, digital-analog converter (DAC) amplifier units 132 and 134, a lens control circuit 136, a detection circuit 137, a stage control mechanism 138, a stage position measuring instrument 139, and storage devices 140 and 142 such as magnetic disk drives. The control computer 110, the memory 112, the deflection control circuit 130, the lens control circuit 136, the detection circuit 137, the stage control mechanism 138, the stage position measuring instrument 139, and the storage devices 140 and 142 are connected to each other through a bus (not shown). The DAC amplifier units 132 and 134 and the blanking aperture array mechanism 204 are connected to the deflection control circuit 130. The sub deflector 209 is composed of at least four electrodes (or “at least four poles”), and controlled by the deflection control circuit 130 through the DAC amplifier 132 disposed for each electrode. The main deflector 208 is composed of at least four electrodes (or “at least four poles”), and controlled by the deflection control circuit 130 through the DAC amplifier 134 disposed for each electrode. Lenses, such as the illumination lens 202, the reducing lens 205, and the objective lens 207 are controlled by the lens control circuit 136. As for the lenses, an electromagnetic lens or an electrostatic lens is used.

The position of the XY stage 105 is controlled by the drive of each axis motor (not shown) which is controlled by the stage control mechanism 138. Based on the principle of laser interferometry, the stage position measurement instrument 139 measures the position of the XY stage 105 by receiving a reflected light from the mirror 210.

A secondary electron emitted from the target object 101 due to irradiation of an electron beam to the target object 101 is detected by the detector 212. Detection data of the detector 212 is output to the detection circuit 137, and, after being converted into digital data by the detection circuit 137, is output to the control computer 110.

In the control computer 110, there are arranged a rasterization processing unit 50, a shot data generation unit 52, a coordinate setting unit 54, a region setting unit 56, a scan processing unit 58, a determination unit 60, a difference calculation unit 62, a determination unit 64, a removal unit 65, a determination unit 66, a mark position calculation unit 68, a determination unit 69, a correction unit 70, a writing control unit 72, and a transmission processing unit 74. Each of the “ . . . units” such as the rasterization processing unit 50, the shot data generation unit 52, the coordinate setting unit 54, the region setting unit 56, the scan processing unit 58, the determination unit 60, the difference calculation unit 62, the determination unit 64, the removal unit 65, the determination unit 66, the mark position calculation unit 68, the determination unit 69, the correction unit 70, the writing control unit 72, and the transmission processing unit 74 includes processing circuitry. The processing circuitry includes, for example, an electric circuit, a computer, a processor, a circuit board, a quantum circuit, a semiconductor device, or the like. Each “ . . . unit” may use common processing circuitry (the same processing circuitry), or different processing circuitry (separate processing circuitry). Information input/output to/from the rasterization processing unit 50, the shot data generation unit 52, the coordinate setting unit 54, the region setting unit 56, the scan processing unit 58, the determination unit 60, the difference calculation unit 62, the determination unit 64, the removal unit 65, the determination unit 66, the mark position calculation unit 68, the determination unit 69, the correction unit 70, the writing control unit 72, and the transmission processing unit 74, and information being operated are stored in the memory 112 each time.

Writing operations of the writing apparatus 100 are controlled by the writing control unit 72. In other words, the writing control unit 72 (an example of a control circuit) controls the writing mechanism 150. Processing of transmitting irradiation time data of each shot to the deflection control circuit 130 is controlled by the transmission control unit 74.

Writing data (chip data) is input from the outside of the writing apparatus 100, and stored in the storage device 140. Chip data defines information on a plurality of figure patterns configuring a chip pattern. Specifically, for example, coordinates for each vertex are defined in the order of configuration of the figure, for each figure pattern. Alternatively, for example, a figure code, coordinates, a size, and the like are defined for each figure pattern.

FIG. 1 shows a configuration necessary for describing the first embodiment. Other configuration elements generally necessary for the writing apparatus 100 may also be included therein.

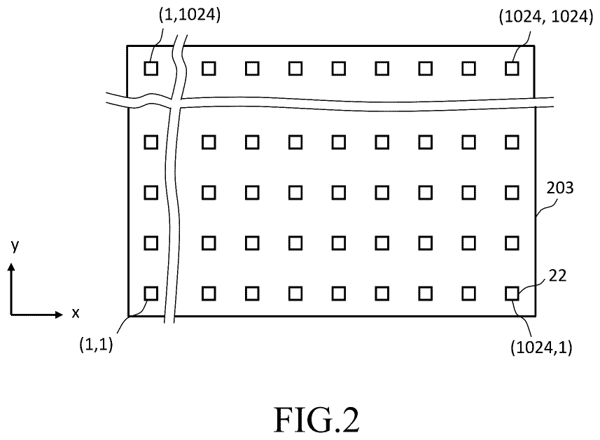

FIG. 2 is a conceptual diagram showing a configuration of a shaping aperture array substrate according to the first embodiment. As shown in FIG. 2, holes (openings) 22 of p rows long (length in the y direction) and q columns wide (width in the x direction) (p≥2, q≥2) are formed, like a matrix, at a predetermined arrangement pitch in the shaping aperture array substrate 203. In the case of FIG. 2, for example, holes 22 of 1024×1024, that is, 1024 holes in the y direction and 1024 holes in the x direction, are formed. The number of the holes 22 is not limited thereto. For example, it is also preferable to form the holes 22 of 512×512 or 32×32. Each of the holes 22 is a rectangle (including square) having the same dimension and shape as each other. Alternatively, each of the holes 22 may be a circle with the same diameter as each other. Multiple beams 20 are formed by letting portions of an electron beam 200 individually pass through a corresponding one of a plurality of holes 22. In other words, the shaping aperture array substrate 203 forms the multiple beams 20.

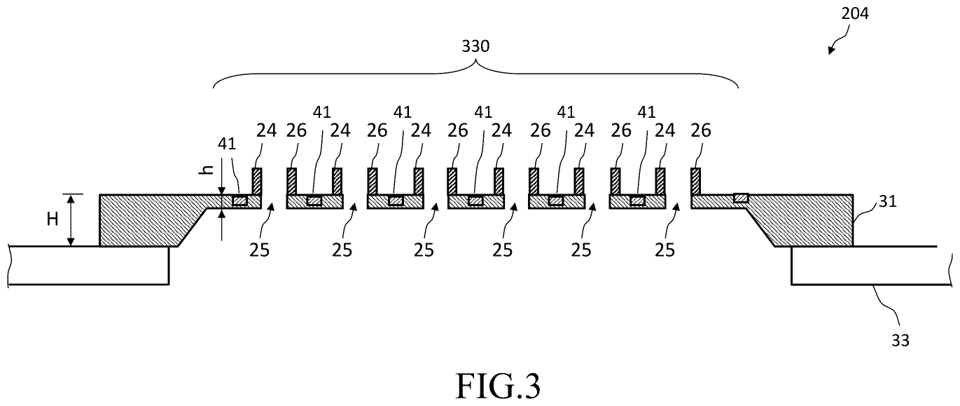

FIG. 3 is a sectional view showing a configuration of a blanking aperture array mechanism according to the first embodiment. In the blanking aperture array mechanism 204, as shown in FIG. 3, a blanking aperture array substrate 31 being a semiconductor substrate made of silicon, etc. is disposed on a support table 33. In a membrane region 330 at the center of the blanking aperture array substrate 31, a plurality of passage holes 25 (openings), through each of which a corresponding one of the multiple beams 20 passes, are formed at positions each corresponding to each hole 22 in the shaping aperture array substrate 203 shown in FIG. 2. A pair of a control electrode 24 and a counter electrode 26, (blanker: blanking deflector), is arranged in a manner such that the electrodes 24 and 26 are opposite to each other across a corresponding one of the plurality of the passage holes 25. A control circuit 41 (logic circuit) which applies a deflection voltage to the control electrode 24 for the passage hole 25 concerned is disposed, inside the blanking aperture array substrate 31, close to each corresponding passage hole 25. The counter electrode 26 for each beam is grounded.

In the control circuit 41, an amplifier (not

shown) (an example of a switching circuit) is arranged. As an example of the amplifier, a CMOS (Complementary MOS) inverter circuit serving as a switching circuit is disposed. With regard to inputs (IN) to the CMOS inverter circuit, either an L (low) potential (e.g., ground potential) lower than a threshold voltage, or an H (high) potential (e.g., 1.5 V) higher than or equal to the threshold voltage is applied as a control signal. According to the first embodiment, in a state where an L potential is applied to the input (IN) of the CMOS inverter circuit, the output (OUT) of the CMOS inverter circuit, which is to be applied to the control circuit 41, becomes a positive potential (Vdd), and then, a corresponding beam is deflected by an electric field due to a potential difference from the ground potential of the counter electrode 26, and is controlled to be in a beam OFF condition by being blocked by the limiting aperture substrate 206. In contrast, in a state (active state) where an H potential is applied to the input (IN) of the CMOS inverter circuit, the output (OUT) of the CMOS inverter circuit becomes a ground potential, and therefore, since there is no potential difference from the ground potential of the counter electrode 26, a corresponding beam is not deflected, and is controlled to be in a beam ON condition by passing through the limiting aperture substrate 206. Blanking control is provided by such deflection.

Next, operations of the writing mechanism 150 will be described. The electron beam 200 emitted from the electron gun 201 (emission source) almost perpendicularly (e.g., vertically) illuminates the whole of the shaping aperture array substrate 203 by the illumination lens 202. A plurality of rectangular holes 22 (openings) are formed in the shaping aperture array substrate 203. The region including all of the plurality of holes 22 is irradiated with the electron beam 200. For example, rectangular multiple beams (a plurality of electron beams) 20 are formed by letting portions of the electron beam 200 applied to the positions of the plurality of holes 22 individually pass through a corresponding one of the plurality of holes 22 in the shaping aperture array substrate 203. The multiple beams 20 individually pass through corresponding blankers of the blanking aperture array mechanism 204. The blanker provides blanking control such that a corresponding beam individually passing becomes in an ON condition during a set writing time (irradiation time).

The multiple beams 20 having passed through the blanking aperture array mechanism 204 are reduced by the reducing lens 205, and travel toward the hole in the center of the limiting aperture substrate 206. Then, the electron beam which was deflected by the blanker of the blanking aperture array mechanism 204 deviates from the hole in the center of the limiting aperture substrate 206 and is blocked by the limiting aperture substrate 206. In contrast, the electron beam which was not deflected by the blanker of the blanking aperture array mechanism 204 passes through the hole in the center of the limiting aperture substrate 206 as shown in FIG. 1. Thus, the limiting aperture substrate 206 blocks each beam which was deflected to be in the OFF state by the blanker of the blanking aperture array mechanism 204. Then, each beam for one shot of the multiple beams 20 is formed by a beam which has been made during a period from becoming beam ON to becoming beam OFF and has passed through the limiting aperture substrate 206. The multiple beams 20 having passed through the limiting aperture substrate 206 are focused by the objective lens 207 so as to be a pattern image of a desired reduction ratio. Then, all of the multiple beams 20 having passed through the limiting aperture substrate 206 are collectively deflected in the same direction by the main deflector 208 and the sub deflector 209 in order to irradiate respective beam irradiation positions on the target object 101. For example, when the XY stage 105 is continuously moving, tracking control is performed by the main deflector 208 so that the beam irradiation position may follow the movement of the XY stage 105. Ideally, the multiple beams 20 irradiating at a time are aligned at a pitch obtained by multiplying the arrangement pitch of a plurality of holes 22 in the shaping aperture array substrate 203 by the desired reduction ratio described above.

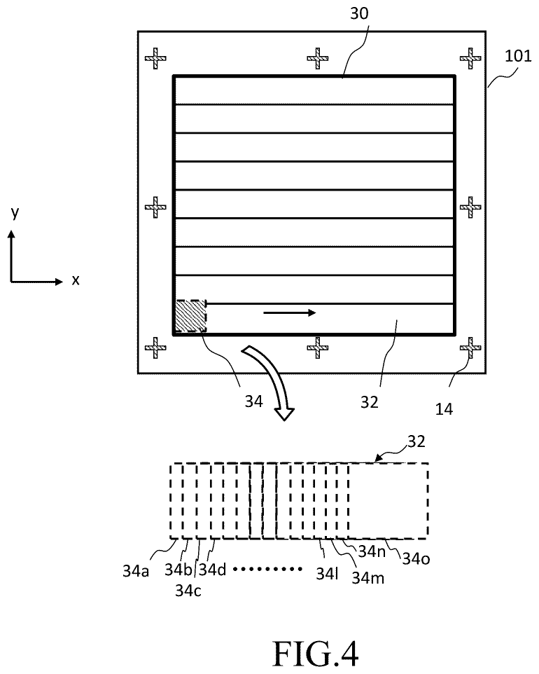

FIG. 4 is a conceptual diagram showing an example of a writing operation according to the first embodiment. As shown in FIG. 4, a writing region 30 (chip region) (bold line) of the target object 101 is virtually divided into a plurality of stripe regions 32 by a predetermined width in the y direction, for example. In the case of FIG. 4, the writing region 30 of the target object 101 is divided in the y direction, for example, into a plurality of stripe regions 32 by the width size being substantially the same as the design size of an irradiation region 34 (writing field) that can be irradiated with one irradiation of the multiple beams 20.

Around the writing region 30 (chip region), a plurality of alignment marks 14 are arranged. It is preferable to use a cross pattern as the alignment mark 14, for example. In FIG. 4, the case where one cross pattern is arranged as each alignment mark 14 is shown, but, it is not limited thereto. For example, it is also preferable to use a set of a large cross pattern and a small cross pattern having the same line width each other, as each alignment mark 14. In that case, a large cross pattern is formed by crossing long line patterns, and a small cross pattern is formed by crossing short line patterns.

FIG. 4 shows the case of writing of multiplicity 1. It is also acceptable to perform multiple writing (N pass writing) meaning repeatedly writing each stripe region 32 by moving the XY stage in the x direction a plurality of s (N s). In that case, preferably, the stripe region 32 is shifted for each pass. For example, in N-pass writing, the position is preferably shifted by 1/N of the width of the stripe region 32. The multiplicity is not limited to 2, it may be 3 or more.

The direction of the position shifting is not limited to the y direction. It is also preferable to shift in the x direction. Next, an example of the writing operation will be explained below.

First, the XY stage 105 is moved to make an adjustment such that the irradiation region 34 of the multiple beams 20 is located at the left end, or at a position further left than the left end, of the first stripe region 32 of the first stripe layer. Then, when performing writing to the first stripe region 32, the XY stage 105 is moved, for example, in the −x direction, so that the writing may relatively proceed in the x direction. The XY stage 105 is moved, for example, continuously at a constant speed.

After performing writing to the first stripe region 32, the stage position is moved in the −y direction by the width size of the stripe region 32.

Next, an adjustment is made so that the irradiation region 34 of the multiple beams 20 can be located at the left end, or at a position further left than the left end, of the second stripe region 32. By moving the XY stage 105, for example, in the −x direction, the writing relatively proceeds in the x direction. Thereby, writing is performed to the second stripe region 32. Hereafter, by repeating similar operations, each stripe region 32 is to be written.

FIG. 4 shows the case where each stripe region 32 is written in the same direction, but, it is not limited thereto. For example, with respect to the stripe region 32 to be written following the stripe region 32 having already been written in the x direction, it may be written in the −x direction by moving the XY stage 105 in the x direction, for example. Thus, due to performing writing while alternately changing the writing direction, the stage moving time can be reduced, which results in reducing the writing time. By one shot of multiple beams having been formed by individually passing through the holes 22 in the shaping aperture array substrate 203, a plurality of shot patterns maximally up to as many as the number of the holes 22 are formed at a time.

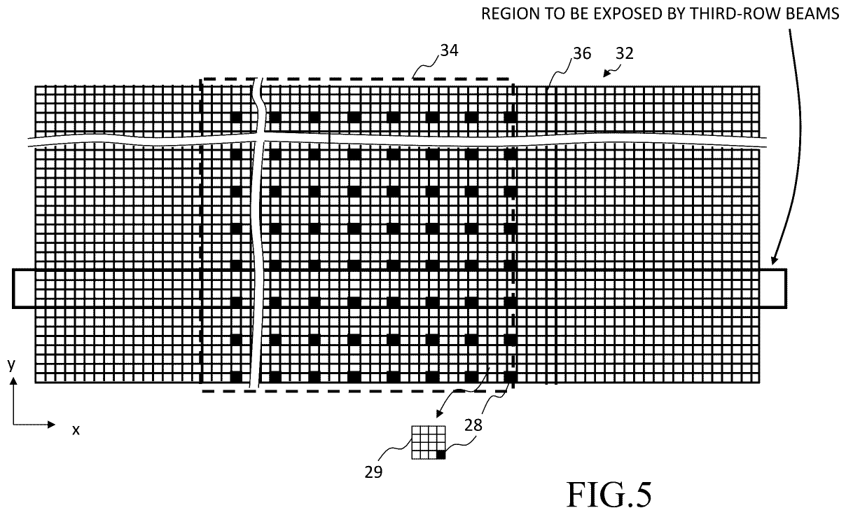

FIG. 5 is an illustration showing an example of an irradiation region of multiple beams and a pixel to be written (writing target pixel) according to the first embodiment. In FIG. 5, the stripe region 32 is divided into a plurality of mesh regions by the beam size of the multiple beams 20, for example. Each mesh region serves as a writing target pixel 36 (beam irradiation unit region, irradiation position). The size of the writing target pixel 36 is not limited to the beam size, and may be any size regardless of beam size. For example, it may be 1/n (n being an integer of 1 or more) of the beam size. FIG. 5 shows the case where the writing region of the target object 101 is divided, for example, in the y direction, into a plurality of stripe regions 32 by the width size being substantially the same as the size of the irradiation region 34 (writing field) that can be irradiated with one irradiation of the multiple beams 20. The x-direction size of the rectangular, including square, irradiation region 34 can be defined by (the number of x-direction beams)×(beam pitch in the x direction). The y-direction size of the rectangular irradiation region 34 can be defined by (the number of y-direction beams)×(beam pitch in the y direction). FIG. 5 shows the case of multiple beams of 1024×1024 (rows×columns) having been simplified to 8×8 (rows×columns). In the irradiation region 34, there are shown a plurality of pixels 28 (beam writing positions) that can be irradiated with one shot of the multiple beams 20. The pitch between adjacent pixels 28 is the beam pitch of the multiple beams. A sub-irradiation region 29 (pitch cell region) is configured by a rectangular, including square, region surrounded by the size of beam pitches in the x and y directions. In the example of FIG. 5, each sub-irradiation region 29 is composed of 4×4 pixels, for example.

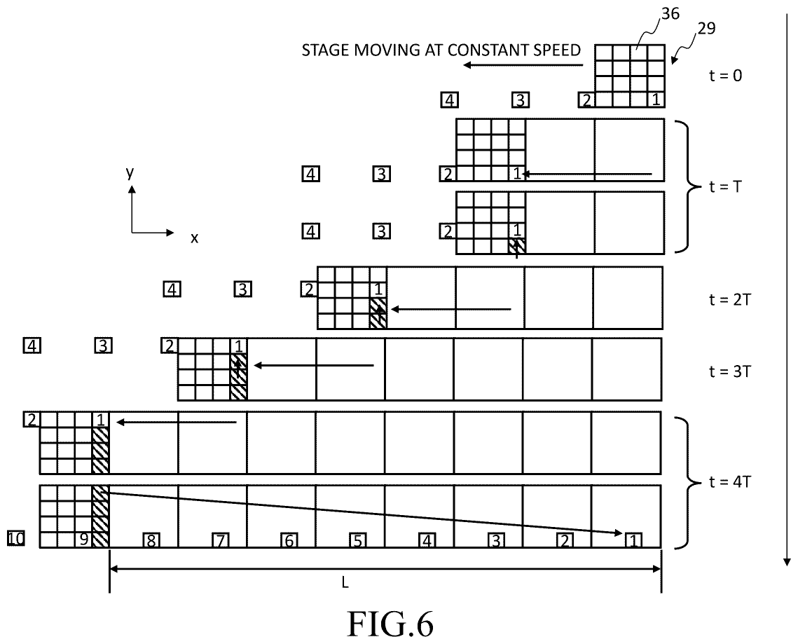

FIG. 6 is an illustration for explaining an example of a multi-beam writing operation according to the first embodiment. FIG. 6 shows the case where the inside of each sub-irradiation region 29 is written with four different Furthermore, the example of FIG. 6 shows a writing beams. operation where the XY stage 105 continuously moves at the speed at which the XY stage 105 moves the distance L of eight beam pitches while a 1/4 region, namely the region of 1/(the number of beams used for irradiation), in each sub-irradiation region 29 is written. In the writing operation shown in FIG. 6, for example, while the XY stage 105 moves the distance L of eight beam pitches, different four pixels in the same sub-irradiation region 29 are written (exposed) by being applied with four shots of the multiple beams 20 at a shot cycle T with shifting the irradiation position (pixel 36) in order by the sub deflector 209. In order that the relative position between the irradiation region 34 and the target object 101 may not be shifted by the movement of the XY stage 105 while these four pixels 36 are written (exposed), the irradiation region 34 is made to follow the movement of the XY stage 105 by collective deflection of all of the multiple beams 20 by the main deflector 208. In other words, a tracking control is performed. After one tracking cycle is completed, tracking is reset to return to the previous (last) tracking starting position. Since writing of the pixels in the first column from the right of each sub-irradiation region 29 has been completed, in the next tracking cycle after resetting the tracking, first, the sub deflector 209 provides deflection such that the beam writing position is adjusted (shifted) to write the second pixel column from the right still not having been written in each sub-irradiation region 29, for example. By repeating this operation during writing the stripe region 32, as shown in the lower part of FIG. 4, the position of the irradiation region 34 of the multiple beams 20 is sequentially moved (shifted), such as the irradiation region 34a, 34b, 34c, . . . 34o, to perform writing.

As described above, an alignment mark of the target object 101 placed on the XY stage 105 is measured before writing the target object.

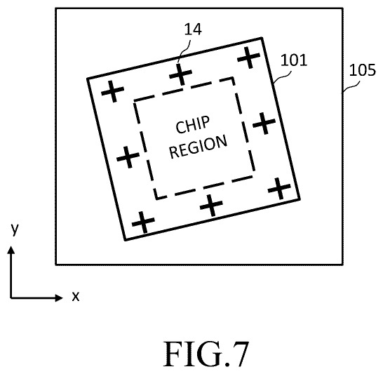

FIG. 7 is an illustration showing an example of a positional relationship between a stage and a target object according to the first embodiment. As shown in FIG. 7, when placing the transferred target object 101 on the XY stage 105, it is difficult to perfectly fit the direction of the target object 101 to the writing coordinate system. FIG. 7 shows the case where the target object 101 is obliquely rotationally shifted. In contrast, each pattern defined by writing data meets the writing coordinate system. Therefore, if writing is performed as it is, a pattern is written on a shifted position. Thus, a plurality of alignment marks 14 are measured in order to correct the position of the pattern defined by writing data, on the basis of the plurality of alignment marks 14.

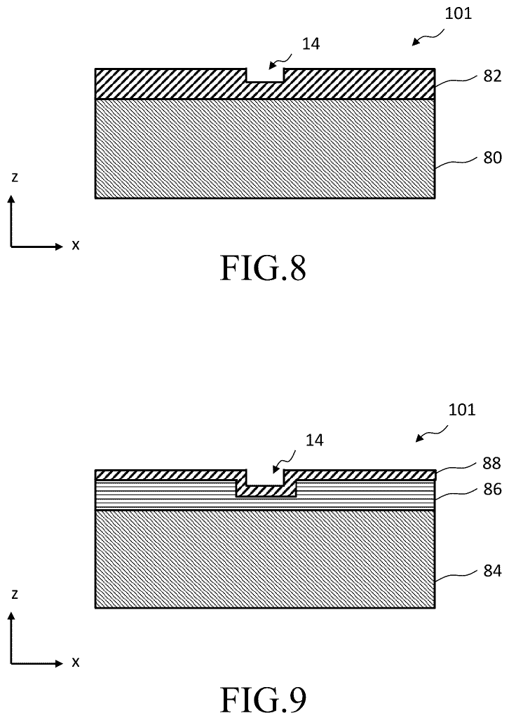

FIG. 8 is a sectional view showing an example of a configuration of an alignment mark according to the first embodiment. FIG. 8 shows the case where an exposure mask is used as the target object 101. As shown in FIG. 8, for example, on a glass substrate 80 of the target object 101, a light shielding film 82 made of chromium (Cr), etc. is formed. Then, a recess is formed in the light shielding film 82. This recessed concave portion is used as the line width of the alignment mark 14. Therefore, the surface of the concave portion and that of the convex portion form the surface of the same light shielding film 82. Thus, the alignment mark 14 is formed in the concave-convex configuration of the same material. Then, resist is applied to the target object 101 (mask) on which the mark is formed. The target object 101 is transferred into the writing apparatus 100 to perform mark measurement.

FIG. 9 is a sectional view showing another example of a configuration of an alignment mark according to the first embodiment. FIG. 9 shows the case where an EUV exposure mask is used as the target object 101. On a low thermal expansion glass substrate 84 of the target object 101, a multilayer film 86 where, for example, molybdenum (Mo) and silicon (Si) are laminated into multiple layers is formed.

Then, a recess is formed in a portion of the multilayer film 86. On the multilayer film 86 including the recess, an absorber film 88 (antireflection film) mainly made of, for example, Cr and tantalum (Ta) is formed. The recessed concave portion of the absorber film 88 formed on the recess portion of the multilayer film 86 is used as the line width of the alignment mark 14. Therefore, the surface of the concave portion and that of the convex portion form the same absorber film 88. Thus, the alignment mark 14 is formed in the concave-convex configuration of the same material. The line width of the concave portion is from 0.2 to 200 μm, for example, 4 to 5 μm. Then, resist is applied to the target object 101 (mask) on which the mark is formed. The target object 101 is transferred into the writing apparatus 100 to perform mark measurement.

Regarding a mark formed by concave and convex portions of the same material such as the alignment mark 14 shown in FIGS. 8 and 9, when the mark is irradiated with an electron beam, the electron yield is too small to achieve good contrast. As a result, there is a problem that the SN ratio is low, and therefore, the alignment mark on the target object cannot be found easily.

Then, in order to obtain contrast, a waveform of a background acquired by scanning a position with no mark is removed from the waveform acquired by scanning a mark.

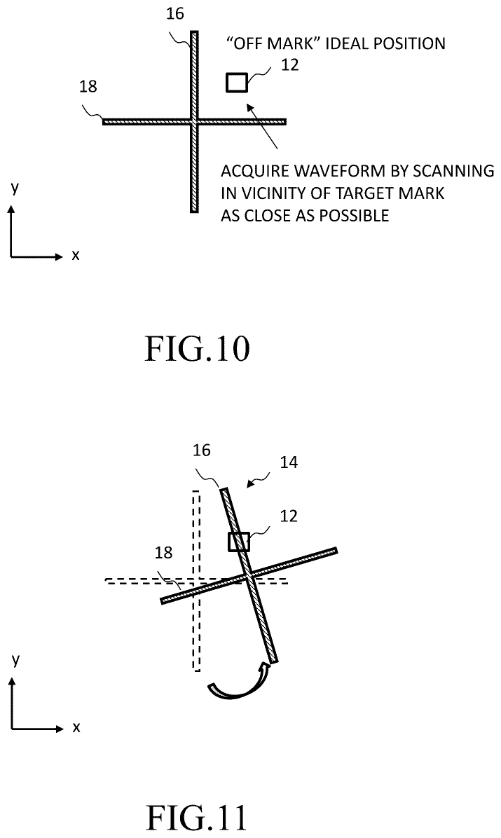

FIG. 10 is an illustration showing an example of a positional relationship between an “off mark” region and an alignment mark according to a comparative example of the first embodiment.

FIG. 11 is an illustration showing another example of a positional relationship between an “off mark” region and an alignment mark according to a comparative example of the first embodiment.

As described above, it is desirable to acquire, in the vicinity of a target mark, a background waveform. Therefore, ideally, as shown in FIG. 10, it is preferable to acquire, as a background waveform, the waveform of an “off mark” region 12 that is a region without a mark, in the vicinity of line patterns 16 and 18 which form a cross pattern to be measured. However, as shown in FIG. 11, there is a possibility that a mark position deviates due to arrangement deviation of a substrate, etc., and a part of the mark overlaps with the “off mark” region 12. Therefore, even when intending to measure the “off mark” region 12, it is difficult to determine whether an acquired waveform is really the waveform of an “off mark” region.

Then, according to the first embodiment, scanning is performed over a plurality of “off mark” regions 12 in order to acquire measured waveforms of the plurality of “off mark” regions 12. It will be specifically described.

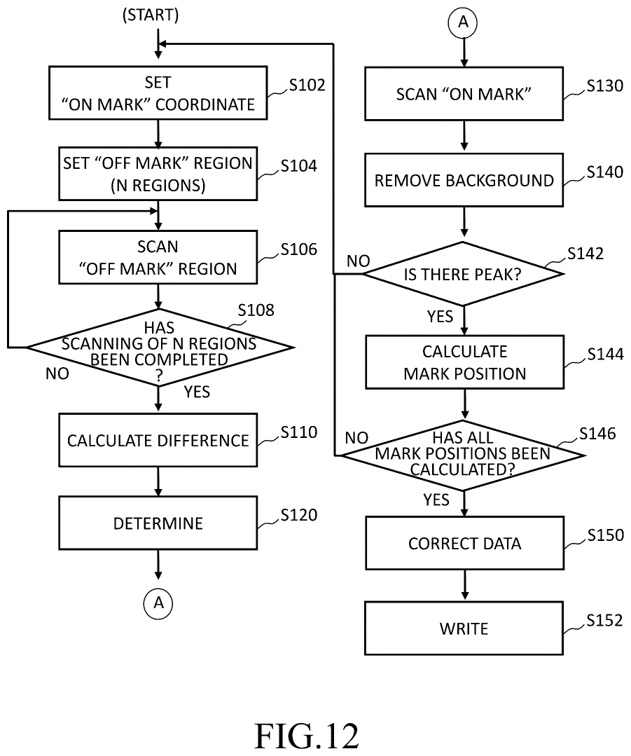

FIG. 12 is a flowchart showing an example of main steps of a writing method according to the first embodiment. In FIG. 12, the writing method of the first embodiment executes a series of steps: an “on mark” coordinate setting step (S102), an “off mark” region setting step (S104), an “off mark” region scanning step (S106), a determining step (S108), a difference calculating step (S110), a determining step (S120), an “on mark” scanning step (S130), a background removing step (S140), a determining step (S142), a mark position calculating step (S144), a determining step (S146), a data correcting step (S150), and a writing step (S152).

In the above steps, the “on mark” coordinate setting step (S102), the “off mark” region setting step (S104), the “off mark” region scanning step (S106), the determining step (S108), the difference calculating step (S110), and the determining step (S120) are main steps of a background waveform acquisition method.

The “on mark” coordinate setting step (S102), the “off mark” region setting step (S104), the “off mark” region scanning step (S106), the determining step (S108), the difference calculating step (S110), the determining step (S120), the “on mark” scanning step (S130), the background removing step (S140), the determining step (S142), and the mark position calculating step (S144) are main steps of a mark position detection method.

In the “on mark” coordinate setting step (S102), the coordinate setting unit 54 sets coordinates of an “on mark” region including a line pattern which forms the alignment mark 14, from design coordinates of one alignment mark 14 in a plurality of alignment marks 14 on the target object 101. As coordinates of an “on mark” region, for example, a position is set, which is moved from the coordinates of the center of the cross pattern of the alignment mark 14, in the range where a target line pattern exists, by a predetermined distance in the extending direction of the target line pattern. It is preferable that the “on mark” region is set in a rectangular region of the same size as that of the irradiation region 34 serving as a beam array region of the multiple beams 20. However, it is not limited thereto. The “on mark” region may be smaller than the irradiation region 34, or larger than the irradiation region 34.

In the “off mark” region setting step (S104), the region setting unit 56 sets, outside the writing region, a plurality of “off mark” regions 12 which are in the vicinity of a target line pattern and do not include the target line pattern, in a plurality of line patterns forming a target alignment mark 14. Preferably, the “off mark” region 12 is set to be the same size as that of the “on mark” region. Specifically, it is preferable that the “off mark” region 12 is set to be a rectangular region of the same size as that of the irradiation region 34 serving as a beam array region of the multiple beams 20. However, it is not limited thereto. Similarly to the “on mark” region, the “off mark” region may be smaller than the irradiation region 34, or larger than the irradiation region 34.

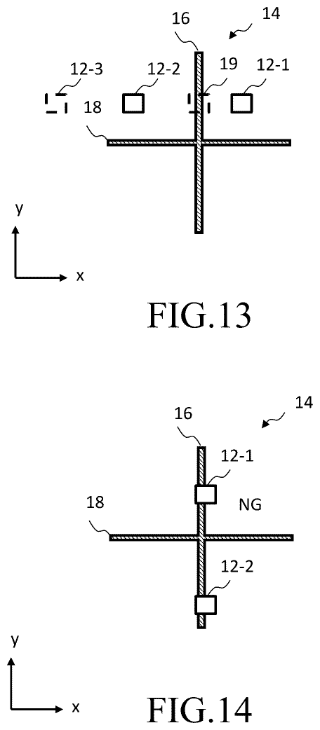

FIG. 13 is an illustration showing an example of a positional relationship among an alignment mark, an “on mark” region, and a plurality of “off mark” regions according to the first embodiment. In order to measure the position of the alignment mark 14, it is necessary to obtain positions in the x and y directions. For obtaining the position in the x direction, the x-coordinate of the line pattern 16 extending in the y direction is measured in the two line patterns 16 and 18 which form the alignment mark 14. For obtaining the position in the y direction, the y-coordinate of the line pattern 18 extending in the x direction is measured in the two line patterns 16 and 18 which form the alignment mark 14.

FIG. 13 shows the case where a plurality of “off mark” regions 12 are set, regarding the line pattern 16 extending in the y direction as a target line pattern, in the two line patterns 16 and 18 which form the alignment mark 14. With respect to the line pattern 16 extending in the y direction, scanning is performed in the x direction in a manner of passing across the line pattern 16 in the width direction of the line pattern 16. Therefore, it is preferable that a plurality of “off mark” regions 12 are aligned in the x direction. Furthermore, preferably, the “off mark” regions 12 are arranged on the both sides of the line pattern 16 to be across from each other. In the example of FIG. 13, across the “on mark” region 19 of the line pattern 16, an “off mark” region 12-1 is set on the x direction side, and an “off mark” region 12-2 is set on the −x direction side. The number of the “off mark” regions 12 is N (N being an integer of 2 or more). What is necessary is that the number of the “off mark” regions 12 is two or more, namely, two, three, or more. Furthermore, the arrangement direction of the “off mark” region 12 is not limited thereto. It is sufficient that a plurality of “off mark” regions 12 are aligned in the vicinity of the line pattern 16 and in the direction not parallel to the y direction in which the line pattern 16 is extending.

FIG. 14 is an illustration showing an example of a positional relationship between an alignment mark, and a plurality of “off mark” regions according to the first embodiment. For example, in the case of setting a plurality of “off mark” regions 12-1 and 12-2 in the y direction to be parallel to the line pattern 16 extending in the y direction, there is a possibility that the plurality of “off mark” regions 12-1 and 12-2 are arranged on the line pattern 16 as shown in FIG. 14. In that case, since it is impossible to determine whether the region is an “off mark” region or not, this arrangement is not acceptable.

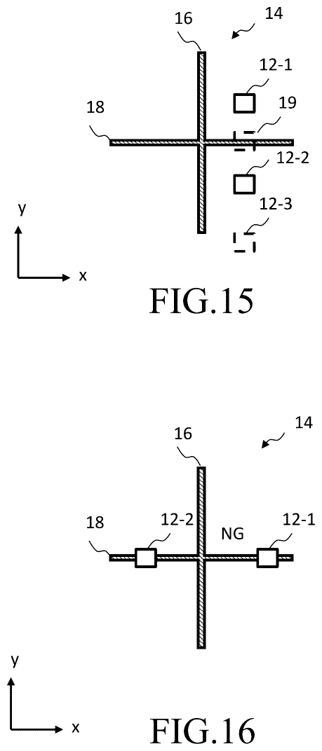

FIG. 15 is an illustration showing another example of a positional relationship among an alignment mark, an “on mark” region, and a plurality of “off mark” regions according to the first embodiment. FIG. 15 shows the case where, with respect to the two line patterns 16 and 18 which form the alignment mark 14, a plurality of “off mark” regions 12 are set regarding the line pattern 18 extending in the x direction as a target line pattern. Concerning the line pattern 18 extending in the x direction, scanning is performed in the y direction in a manner of passing across the line pattern 18 in the width direction of the line pattern 18. Therefore, it is preferable that a plurality of “off mark” regions 12 are aligned in the y direction. Furthermore, preferably, the “off mark” regions 12 are arranged on the both sides of the line pattern 18 to be across from each other. In the example of FIG. 15, across the “on mark” region 19 of the line pattern 18, an “off mark” region 12-1 is set on the +y direction side, and an “off mark” region 12-2 is set on the −y direction side. The number of the “off mark” regions 12 is N (N being an integer of 2 or more). What is necessary is that the number of the “off mark” regions 12 is two or more, namely, two, three, or more. Furthermore, the arrangement direction of the “off mark” region 12 is not limited thereto. It is sufficient that a plurality of “off mark” regions 12 are aligned in the vicinity of the line pattern 18 and in the direction not parallel to the x direction in which the line pattern 18 is extending.

FIG. 16 is an illustration showing an example of a positional relationship between an alignment mark, and a plurality of “off mark” regions according to the first embodiment. For example, in the case of setting a plurality of “off mark” regions 12-1 and 12-2 in the x direction to be parallel to the line pattern 18 extending in the x direction, there is a possibility that the plurality of “off mark” regions 12-1 and 12-2 are arranged on the line pattern 18 as shown in FIG. 16. In that case, since it is impossible to determine whether the region is an “off mark” region or not, this arrangement is not acceptable.

In the “off mark” region scanning step (S106), for each alignment mark 14 of the target object 101, the scanning mechanism scans the target object 101 with an electron beam, at a plurality of “off mark” regions 12 which are in the vicinity of the line pattern 16 (18) and are arranged in the direction not parallel to the direction in which the line pattern 16 (18) is extending. Specifically, for each “off mark” region 12, the scanning mechanism scans the target “off mark” region 12 concerned with an electron beam. First, by moving the XY stage 105, the target object 101 is moved to a position where the target “off mark” region 12 can be irradiated with an electron beam. For example, it is preferable for the irradiation region 34 of the multiple beams 20 and the “off mark” region 12 to be moved to have a positional relationship of being overlapped with each other without beam deflection at the time of irradiation of multiple beams 20.

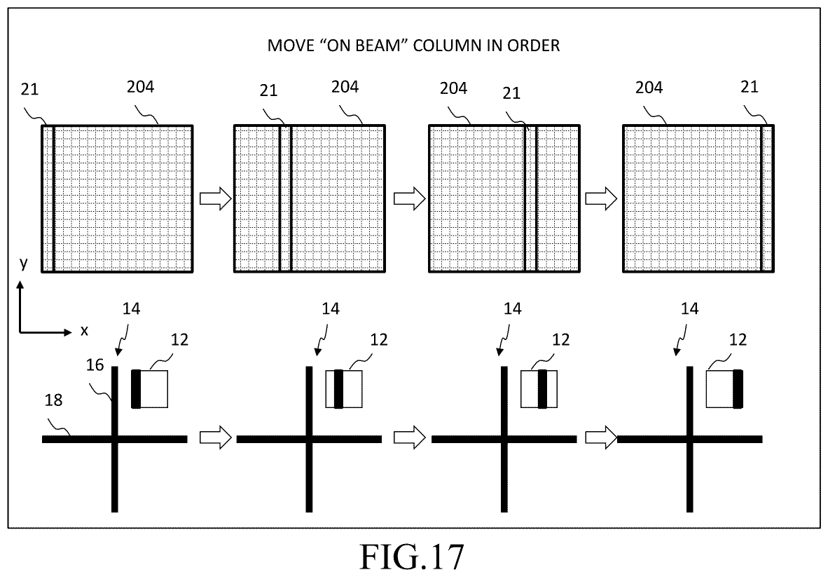

FIG. 17 is an illustration for explaining an example of a scanning method over the “off mark” region 12 according to the first embodiment. In FIG. 17, scanning the “off mark” region 12 is performed by moving a beam array of “ON” beams in the multiple beams 20 in a scanning direction in order. FIG. 17 shows an example of the case of scanning in the x direction over the “off mark” region 12 which is set in the vicinity of the line pattern 16 extending in the y direction. Specifically, a beam group 21, composed of y-direction beams, which is the first column in the x direction in the multiple beams 20 is made to be “ON beam” by the blanking aperture array mechanism 204 being an example of the scanning mechanism. The other beams are controlled as “beam OFF”. Next, the beam group 21, composed of y-direction beams, which is the second column in the x direction is made to be “ON beam”. The other beams are treated as “beam OFF”. Then, the beam group 21, composed of y-direction beams, which is the third column in the x direction is made to be “ON beam”. The other beams are defined to be the “beam OFF”. After this, by operating similarly, up to the beam group 21 of y-direction beams, which is the last column in the x direction, the beam group 21 can scan in the x direction the “off mark” region 12. In other words, the blanking aperture array mechanism 204 switchingly moves (switching movement) the ON beam group 21, composed of y-direction beams in the multiple beams 20, in the x direction from the first column to the last one in order.

In the case of scanning in the y direction over the “off mark” region 12 which is set in the vicinity of the line pattern 18 extending in the x direction, the blanking aperture array mechanism 204 switchingly moves (switching movement) the ON beam group 21, composed of x-direction beams in the multiple beams 20, in the y direction from the first row to the last one in order.

In the examples described above, the beam group 21 is not limited to one column/row beam. The beam group 21 may be composed of beams in adjacent plural columns/rows. For example, it may be ON beam per two columns/rows.

The method of beam scanning is not limited thereto.

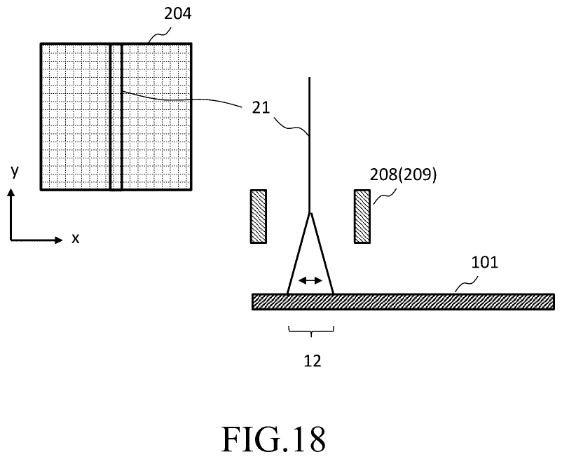

FIG. 18 is an illustration for explaining another example of a scanning method over the “off mark” region 12 according to the first embodiment. In FIG. 18, using the blanking aperture array mechanism 204, one beam group 21, composed of beams aligned in the direction perpendicular to the scanning direction, for example, is used as “ON beam”, and the other beams are treated as “beam OFF”. Then, using the main deflector 208 (or sub deflector 209) being another example of the scanning mechanism, the beam group 21 can scan the “off mark” region 12 by collectively performing beam deflection the beam group 21 in the scanning direction.

In the examples described above, the beam group 21 is not limited to one column/row beam. The beam group 21 may be composed of beams in adjacent plural columns/rows. For example, it may be ON beam per two columns/rows.

Due to the scanning over the “off mark” region 12 described above, a secondary electron and a reflected electron are emitted from the “off mark” region 12 irradiated with an electron beam. The emitted secondary electron and reflected electron are detected by the detector 212, and output to the control computer 110 through the detection circuit 137.

In the determining step (S108), the determination unit 60 determines, for each line pattern forming the alignment mark 14, whether performing scanning over the prescribed N “off mark” regions 12 has been completed. If the scanning over the N “off mark” regions 12 is not completed, it returns to the “off mark” region scanning step (S106), and repeats the “off mark” region scanning step (S106) until the N “off mark” regions 12 has been scanned. If the scanning over the N “off mark” regions 12 is completed, it proceeds to the difference calculating step (S110).

Through the process described above, measured waveforms of a plurality of “off mark” regions 12 can be acquired. These measured waveforms are stored in the storage device 142, for example.

In the difference calculating step (S110), the difference calculation unit 62 calculates a first difference and a second difference, for each combination, at least one combination, obtained by combining each two measured waveforms in a plurality of measured waveforms acquired from a plurality of “off mark” regions 12. Specifically, with respect to the combination concerned, a difference (A-B) (first difference) is obtained by subtracting a measured waveform B (second measured waveform) from a measured waveform A (first measured waveform), and a difference (B-A) (second difference) is obtained by subtracting a measured waveform A from a measured waveform B.

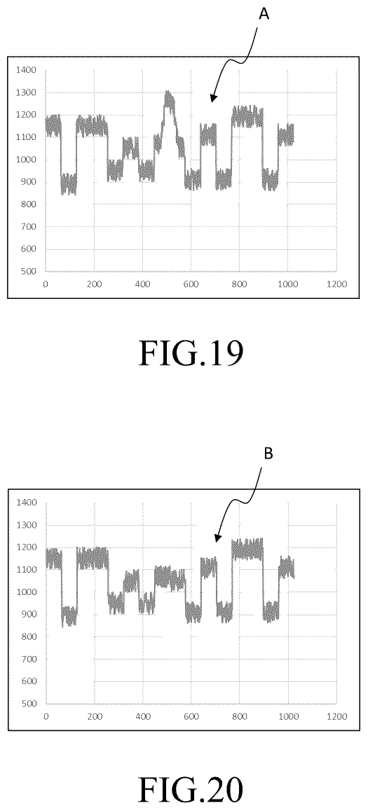

FIG. 19 is an illustration showing an example of a measured waveform A according to the first embodiment.

FIG. 20 is an illustration showing an example of a measured waveform B according to the first embodiment.

In FIGS. 19 and 20, the ordinate axis represents a detection intensity, and the abscissa axis represents a position. FIGS. 19 and 20 show the case where the number of the multiple beams 20 in the x direction is 1024. Thereby, in each of the measured waveforms A and B, 1024 detection values in the x direction exist.

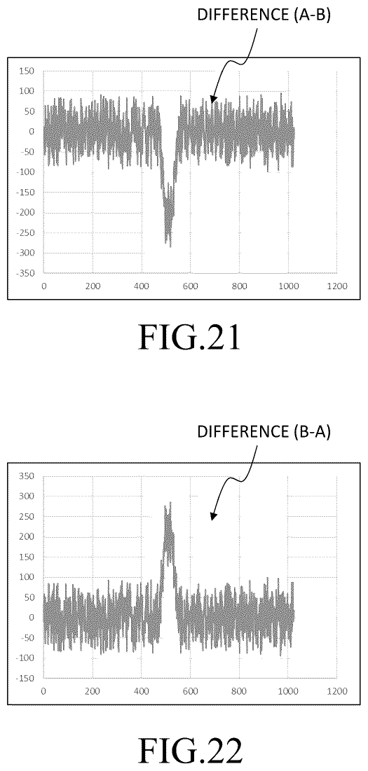

FIG. 21 is an illustration showing an example of a difference waveform (A-B) according to the first embodiment.

FIG. 22 is an illustration showing an example of a difference waveform (B-A) according to the first embodiment.

FIG. 21 shows an example of a difference waveform (A-B) obtained by subtracting the measured waveform B shown in FIG. 20 from the measured waveform A shown in FIG. 19. FIG. 22 shows an example of a difference waveform (B-A) obtained by subtracting the measured waveform A shown in FIG. 19 from the measured waveform B shown in FIG. 20. If a certain positive peak (convex upward) which shows a line pattern, etc. exists in the measured waveform B, when the measured waveform B is subtracted from the measured waveform A, since the sign of each intensity value of the measured waveform B is reversed, a negative peak (convex downward) appears in the difference waveform. In contrast, when the measured waveform A is subtracted from the measured waveform B, since the sign of each intensity value of the measured waveform B is not reversed, a positive peak (convex upward) appears in the difference waveform.

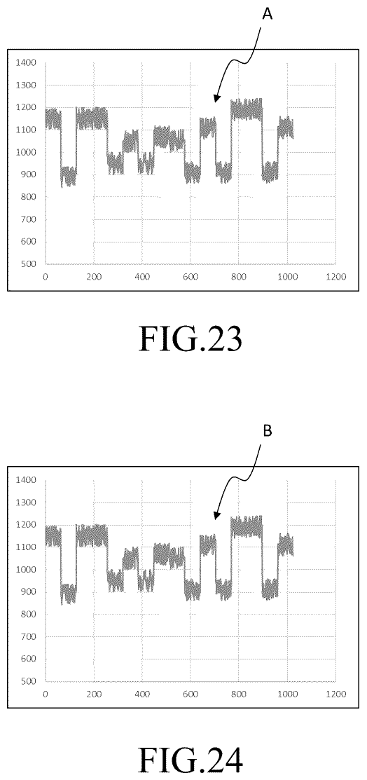

FIG. 23 is an illustration showing another example of the measured waveform A according to the first embodiment.

FIG. 24 is an illustration showing another example of the measured waveform B according to the first embodiment.

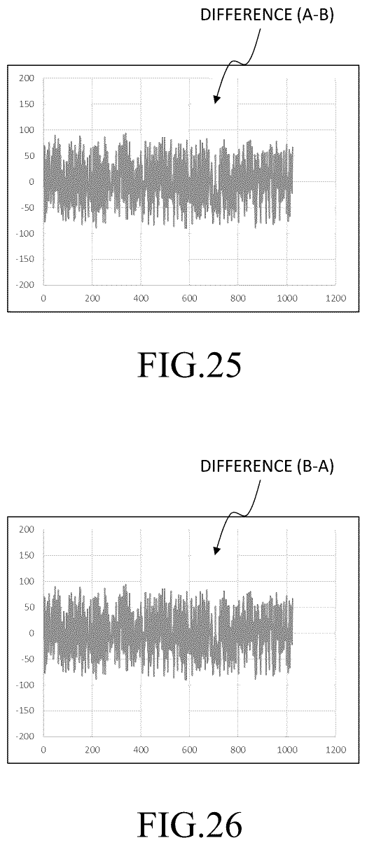

FIG. 25 is an illustration showing another example of the difference waveform (A-B) according to the first embodiment.

FIG. 26 is an illustration showing another example of the difference waveform (B-A) according to the first embodiment.

FIG. 25 shows an example of a difference waveform (A-B) obtained by subtracting the measured waveform B shown in FIG. 24 from the measured waveform A shown in FIG. 23. FIG. 26 shows an example of a difference waveform (B-A) obtained by subtracting the measured waveform A shown in FIG. 23 from the measured waveform B shown in FIG. 24. If a certain peak which shows a line pattern, etc. exists in neither the measured waveform A nor the measured waveform B, no peak appears in the difference waveform (A-B) obtained by subtracting the measured waveform B from the measured waveform A. Similarly, no peak appears in the difference waveform (B-A) obtained by subtracting the measured waveform A from the measured waveform B.

In the determining step (S120), the determination unit 64 determines, for each alignment mark 14, the waveform of the background which is not a mark, in a plurality of waveforms measured by performing scanning over a plurality of “off mark” regions 12. Here, the determination unit 64 determines, for each line pattern forming a portion of the alignment mark 14, the waveform of the background which is not the target line pattern, in a plurality of waveforms measured by scanning a plurality of “off mark” regions 12. Specifically, the determination unit 64 determines the waveform of the background, based on a difference waveform (A-B) and a difference waveform (B-A). Furthermore, it operates as described below in details.

First, the determination unit 64 determines whether an upward convex peak exists in the difference waveform (A-B). If the upward convex peak exists in the difference waveform (A-B), the measured waveform B is determined to be a background waveform G. If the upward convex peak does not exist in the difference waveform (A-B), the determination unit 64 determines whether an upward convex peak exists in the difference waveform (B-A). Then, when an upward convex peak exists in the difference waveform (B-A), the measured waveform A is determined to be a background waveform G. When an upward convex peak does not exist in the difference waveform (B-A), that is, when an upward convex peak exists in neither the difference waveform (A-B) nor the difference waveform (B-A), both the measured waveforms A and B are determined to be background waveforms G. Alternatively, it is also preferable that any one of the two is determined to be a background waveform G.

In the examples of FIGS. 21 and 22, no upward convex peak exists in the difference waveform (A-B). However, an upward convex peak exists in the difference waveform (B-A). Therefore, the measured waveform A is determined to be a background waveform G.

In the examples of FIGS. 25 and 26, an upward convex peak exists in neither the difference waveform (A-B) nor the difference waveform (B-A). Therefore, both the measured waveforms A and B are determined to be background waveforms G. Alternatively, it is also preferable that any one of the two is determined to be a background waveform G.

The measured waveform having been determined to be the background waveform G is output to the storage device 142, and stored therein with the position of the “off mark” region 12.

Now, the alignment mark 14 is formed by a line pattern being a concave portion as shown in FIGS. 8 and 9. If the concave portion can be sharply formed, the peak is detectable as a downward convex negative peak. However, when the line width size of the concave portion is small, the concave portion is formed by a gentle sloping surface, not sharply formed, from a viewpoint of processing accuracy. In fact, the concave portion of the alignment mark 14 whose small_line width is a several μm order is formed by a gentle sloping surface. When the concave portion is formed by a gentle sloping surface, the peak is detected as an upward convex positive peak. This is because, when the concave portion is sharp, with respect to a secondary electron and a reflected electron emitted by electron beam irradiation, compared with the secondary electron emitted isotropically, the intensity of the reflected electron emitted from the bottom toward the direction opposite to the incident direction of an electron beam, that is upward direction, is detected along the sharp concave portion shape. On the other hand, if the concave portion is formed by a gentle sloping surface, not sharply formed, since there is almost no bottom perpendicular to the incident direction of an electron beam and is mostly a sloping surface, the intensity of the secondary electron emitted from the sloping surface isotropically is dominant than that of the reflected electron emitted upward. When the intensity of a secondary electron is dominant, if the line width of the concave portion is small, the peak is detected as an upward convex positive peak. Therefore, it is sufficient for the determination unit 64 to determine whether there is an upward convex peak in the difference waveform.

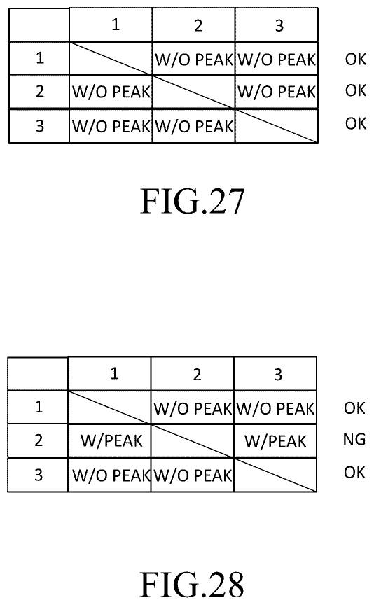

FIG. 27 is an illustration showing an example of a result of a difference waveform for each combination in the case of there being three “off mark” regions according to the first embodiment.

FIG. 28 is an illustration showing another example of a result of a difference waveform for each combination in the case of there being three “off mark” regions according to the first embodiment.

For example, as shown in FIG. 13, when the three “off mark” regions 12-1, 12-2, and 12-3 are set for the line pattern 16, a plurality of combinations each composed of two “off mark” regions are set. Here, there can be three groups, namely, a group of the “off mark” regions 12-1 and 12-2, a group of the “off mark” regions 12-2 and 12-3, and a group of the “off mark” regions 12-1 and 12-3. In FIGS. 27 and 28, the measured waveform of the “off mark” region 12-1 is indicated by “1”, the measured waveform of the “off mark” region 12-2 is indicated by “2”, and the measured waveform of the “off mark” region 12-3 is indicated by “3”. The ordinate column shows a waveform from which another waveform is subtracted, and the abscissa row shows a waveform to subtract.

In the example of FIG. 27, there is no upward convex peak in the difference waveform (1-2), and there is no upward convex peak in the difference waveform (2-1). Therefore, the determination unit 64 determines to be (OK) meaning that both the measured waveforms 1 and 2 can be background waveforms G. There is no upward convex peak in the difference waveform (1-3), and there is no upward convex peak in the difference waveform (3-1). Therefore, the determination unit 64 determines to be (OK) meaning that both the measured waveforms 1 and 3 can be background waveforms G. There is no upward convex peak in the difference waveform (2-3), and there is no upward convex peak in the difference waveform (3-2). Therefore, the determination unit 64 determines to be (OK) meaning that both the measured waveforms 2 and 3 can be background waveforms G.

In the example of FIG. 28, there is no upward convex peak in the difference waveform (1-2), but there is an upward convex peak in the difference waveform (2-1). Therefore, the determination unit 64 determines to be (OK) meaning that the measured waveform 1 can be a background waveform G. There is no upward convex peak in the difference waveform (1-3), and there is no upward convex peak in the difference waveform (3-1). Therefore, the determination unit 64 determines to be (OK) meaning that both the measured waveforms 1 and 3 can be background waveforms G. There is an upward convex peak in the difference waveform (2-3), and there is no upward convex peak in the difference waveform (3-2). Therefore, the determination unit 64 determines to be (OK) meaning that the measured waveform 3 can be a background waveform G. Thus, the measured waveforms 1 and 2 can be background waveforms G (OK). However, the measured waveform 2 is determined to be (NG) meaning that it cannot be used as a background waveform G.

Although, in the examples described above, the background waveform is determined based on a difference between two measured waveforms, the method for determining a background waveform is not limited thereto.

The difference calculation unit 62 calculates a parameter R_{ssd} using a difference (Tᵢ−Wᵢ) between a template waveform Tᵢ for determining a background waveform and a measured waveform Wᵢ concerned, for each measured waveform in a plurality of measured waveforms Wᵢ obtained from a plurality of “off mark” regions 12.

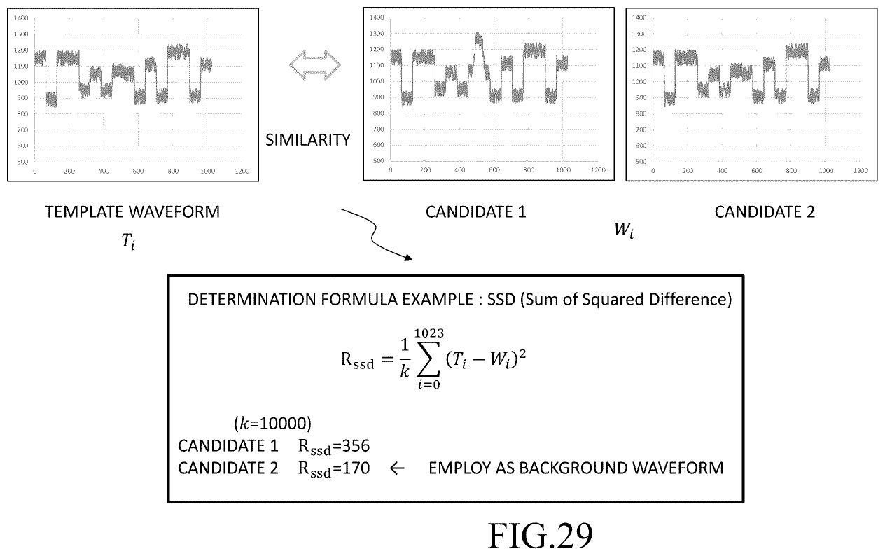

FIG. 29 is an illustration for explaining an example of a method for determining a background waveform, using a template, according to the first embodiment. First, a template waveform Tᵢ for determination of a background waveform is prepared in advance. As the template waveform Tᵢ, for example, a measured waveform obtained as a result of scanning performed on the position thoroughly away from the alignment mark 14 can be used. Alternatively, as the template waveform Tᵢ, it is also preferable to form a waveform which has features of previous background waveforms. The template waveform Tᵢ is stored in the storage device 142, for example. Then, as shown in FIG. 29, a sum of squared difference between the template waveform Tᵢ and a measured waveform Wᵢ concerned is calculated for each measured waveform. Since FIG. 29 shows the case there are 1024 measurement points, in order to match the digit of the sum of squared difference with the digit of intensity of each measurement point of the waveform, a value obtained by dividing the sum of squared difference by a coefficient k is calculated as a parameter R_{ssd}. As the coefficient k, 10000 is used, for example. FIG. 29 shows the case where the calculation result with respect to the measured waveform A, serving as a candidate 1, is a parameter R_{ssd}=356, and the calculation result with respect to the measured waveform B, serving as a candidate 2, is a parameter R_{ssd}=170.

The determination unit 64 determines, in a plurality of measured waveforms being candidates, a measured waveform having a high similarity to the template waveform Tᵢ as a waveform of the background. Specifically, the determination unit 64 determines, in the plurality of measured waveforms being candidates, a measured waveform which makes the parameter R_{ssd} smaller as a waveform of the background. In the example of FIG. 29, the measured waveform B, serving as the candidate 2, with a small parameter R_{ssd} is determined as the background waveform G.

The measured waveform having been determined to be a background waveform is output to the storage device 142, and stored therein with the position of the “off mark” region 12 concerned.

As described above, by using a measured waveform obtained based on a plurality of “off mark” regions 12 in the vicinity of the alignment mark 14, a highly accurate background waveform can be acquired.

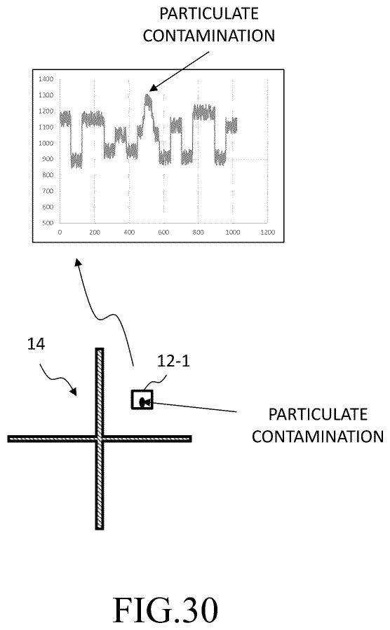

FIG. 30 is an illustration showing an example of a measured waveform whose difference waveform has a peak according to the first embodiment. As described above, when an upward convex peak exists in a difference waveform (A-B), a waveform peak exists in the measured waveform A. Alternatively, when an upward convex peak exists in a difference waveform (B-A), a waveform peak exists in the measured waveform B. Therefore, it apparently seems to be preferable to use, as it is, the measured waveform in which an upward convex peak exists, as a measured waveform C of the “on mark” region 19 where the mark exists. However, there is a possibility that the cause of generation of the peak is a particulate contamination on the target object 101 as shown in the example of FIG. 30. Then, according to the first embodiment, even when a peak exists in the measured waveform of the “off mark” region 12 used for determining the background waveform G, a “on mark” region including a portion of a mark is daringly newly searched for.

In the “on mark” scanning step (S130), the scanning mechanism scans the target object 101 with an electron beam, at the “on mark” region 19 including the target line pattern 16 (18). The method of performing scanning over the “on mark” region 19 is the same as that of scanning the “off mark” region 12.

In the background removing step (S140), the removal unit 65 removes a background waveform G which has been acquired by determination, from a measured waveform C measured by performing scanning over the “on mark” region 19 including a line pattern. Specifically, a difference waveform (C-G) is calculated by subtracting a background waveform from a measured waveform C of the “on mark” region.

In the determining step (S142), the determination unit 66 determines whether an upward convex peak exists in a difference waveform (C-G) which is obtained by removing the background waveform G from the measured waveform C of the “on mark” region 19. If an upward convex peak exists in the difference waveform (C-G) obtained by removing the background waveform G from the measured waveform C of the “on mark” region, it proceeds to the mark position calculating step (S144). If an upward convex peak does not exist in the difference waveform (C-G), it returns to the “on mark” coordinate setting step (S102), and then, while shifting the coordinates of the “on mark” region 19, each step from the “on mark” coordinate setting step (S102) to the determining step (S142) is repeated until an upward convex peak exists in the difference waveform (C-G) which is obtained by removing the background waveform G from the measured waveform C of the “on mark” region 19.

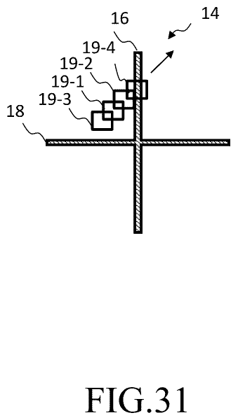

FIG. 31 is an illustration for explaining a method of shifting an “on mark” region according to the first embodiment. The example of FIG. 31 shows the case where, in the two line patterns 16 and 18 which form the alignment mark 14, the “on mark” region 19 including the line pattern 16 extending in the y direction is searched for. If the arrangement position of the target object 101 on the XY stage 105 deviates, the line pattern 16 (18) is not necessarily included in the “on mark” region 19 whose coordinates have been set. If not included, no peak appears in the measured waveform obtained in the “on mark” scanning step (S130). Therefore, when a peak does not exist even if the background waveform G is removed, the “on mark” region 19 including a line pattern is searched for while shifting the “on mark” region 19. In such a case, as shown in FIG. 31, the second “on mark” region 19-2 is set, shifted from the first “on mark” region 19-1, in the 45° direction, which is an intermediate direction between the x direction and the y direction, to be overlapped with a part of the “on mark” region 19-1. When there is no peak in the “on mark” region 19-2, the third “on mark” region 19-3 is set in the reverse direction (225°), reverse to the “on mark” region 19-2, to be overlapped with a part of the “on mark” region 19-1. When there is no peak in the “on mark” region 19-3, the fourth “on mark” region 19-4 is set in the 45° direction from the “on mark” region 19-2 to be overlapped with a part of the “on mark” region 19-2. Henceforth, it is repeated while shifting the position with alternately changing the direction until a peak appears. Thus, whenever the “on mark” region 19 is set, a plurality of “off mark” regions 12 are set in the vicinity of the “on mark” region 19 concerned. By shifting the position of the “on mark” region 19 to be partially overlapped, omission in detection of a line pattern can be prevented.

In the mark position calculating step (S144), the mark position calculation unit 68 calculates a mark position from a measured waveform from which the background waveform G has been removed.

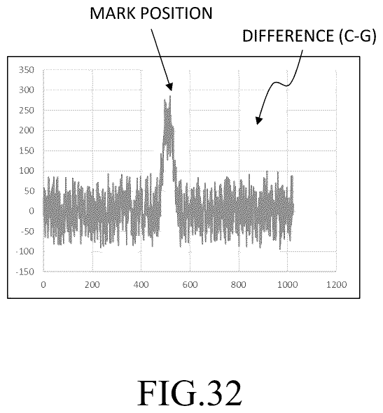

FIG. 32 is an illustration showing an example of a mark position according to the first embodiment. The position of an upward convex peak appearing in the difference waveform (C-G) is the position of a target line pattern. Since the position of the “on mark” region 19 is known, the position of the target line pattern can be calculated.

After calculating the x position (or the y position) of the line pattern 16 (or 18) which is one of two line patterns forming the alignment mark 14, each step from the “on mark” coordinate setting step (S102) to the mark position calculating step (S144) is performed with respect to the other line pattern 18 (or 16) of a pair. By this, the y position (or the x position) of the line pattern 18 (or 16) is calculated.

If the x position of the line pattern 16 extending in the y direction and the y position of the line pattern 18 extending in the x direction are known, the center coordinates (x, y) of the target alignment mark 14 can be obtained. For more precise calculation, for example, the x positions of the line pattern 16 are measured at the positions on the y and −y direction sides of the line pattern 18. Similarly, for example, the y positions of the line pattern 18 are measured at the positions on the x and −x direction sides of the line pattern 16. Then, the mean position of the two x positions and the mean position of the two y positions are calculated as the center coordinates (x, y) of the target alignment mark 14.

By the process described above, the position of the target alignment mark 14 can be detected.

In the determining step (S146), the determination unit 69 determines whether the positions of all the alignment marks 14 have been calculated. If not all of the positions of the alignment marks 14 have been calculated, it returns to the “on mark” coordinate setting step (S102), and each step from the “on mark” coordinate setting step (S102) to the mark position calculating step (S144) is repeated until the positions of all of the alignment marks 14 have been calculated. In other words, each step described above is performed for each of the alignment marks 14.

By the process described above, the position of each of the alignment marks 14 can be detected.

In the data correcting step (S150), the correction unit 70 corrects the position of a pattern to be written, using calculated positions of a plurality of alignment marks 14.

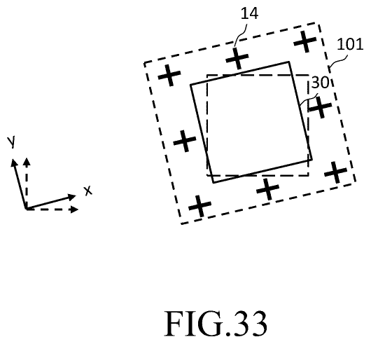

FIG. 33 is an illustration showing an example of a method of correcting data according to the first embodiment. Each pattern data defined in writing data is defined on the basis of each alignment mark 14 in the state where the target object 101 has been arranged on the design position. Accordingly, each pattern data is defined along with the writing coordinate system. However, positional deviation and rotational deviation from the design position have occurred with regard to the target object 101 which is actually arranged on the XY stage 105. Therefore, the position of each pattern data is corrected in response to the positional deviation and rotational deviation, on the basis of an actually measured position of each alignment mark 14.

In the writing step (S152), first, the rasterization processing unit 50 reads chip pattern data (writing data) from the storage device 140, and performs rasterization processing. Specifically, a pattern density (pattern area density) is calculated for each pixel 36.

Next, the shot data generation unit 52 calculates, for each pixel 36, a dose D with which the pixel 36 concerned is irradiated. For example, the dose D can be calculated by multiplying a preset base dose D_{base}, a proximity effect correction dose Dₚ, and a pattern area density p. The proximity effect correction dose Dₚ can be obtained as a relative value standardized by defining the base dose D_{base} to be 1. Thus, it is preferable to obtain the dose D to be in proportion to a pattern area density calculated for each pixel 36. With respect to the proximity effect correction dose Dₚ, the writing region (e.g., in this case, stripe region 32) is virtually divided into a plurality of proximity mesh regions (mesh regions for proximity effect correction calculation) by a predetermined size. The size of the proximity mesh region is preferably about 1/10 of the influence range of the proximity effect, such as about 1 μm. Then, writing data is read from the storage device 140, and, for each proximity mesh region, a pattern density ρ′ (pattern area density) of a pattern arranged in the proximity mesh region concerned is calculated.

Next, a proximity effect correction dose Dₚ for correcting a proximity effect is calculated for each proximity mesh region. A correction model of the proximity effect correction dose Dₚ and its calculation method may be the same as those used in the conventional single beam writing system.

The shot data generation unit 52 calculates, for

each pixel 36, an irradiation time “t” of an electron beam for applying a calculated dose D to the pixel 36 concerned. The irradiation time “t” can be obtained by dividing the dose D by a current density J. Thereby, a dose map (actually, an irradiation time map) in which irradiation time data (shot data) for each pixel 36 is defined is generated.

Then, under the control of the writing control unit 72, the writing mechanism 150 writes a pattern whose position has been corrected on the target object 101 using the multiple beams 20.

As described above, according to the first embodiment, it is possible to highly accurately acquire a background waveform in the vicinity of a mark by a simple method.

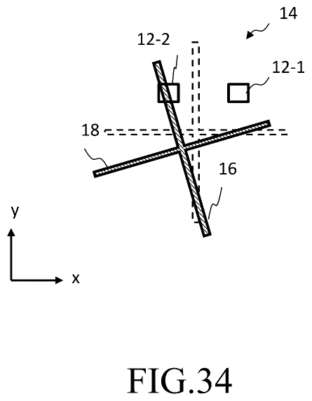

FIG. 34 is an illustration showing an example of a positional relationship among an alignment mark, an “on mark” region, and a plurality of “off mark” regions according to a modified example of the first embodiment. FIG. 34 shows the case where, with respect to the two line patterns 16 and 18 which form the alignment mark 14, a plurality of “off mark” regions 12 are set regarding the line pattern 16 extending in the y direction as a target line pattern. In the example of FIG. 34, across the “on mark” region 19 of the line pattern 16, an “off mark” region 12-1 is set on the +x direction side, and an “off mark” region 12-2 is set on the −x direction side. In that case, as shown in FIG. 34, there is a possibility that a mark position deviates due to arrangement deviation of a substrate, etc., and a part of the mark overlaps with the “off mark” region 12-2, for example. Even in such a case, in the difference calculating step (S110) described above, a difference (A-B) (first difference) is obtained by subtracting a measured waveform B (second measured waveform) from a measured waveform A (first measured waveform), and a difference (B-A) (second difference) is obtained by subtracting a measured waveform A from a measured waveform B. Thus, the case of performing difference calculation twice for the two measured waveforms has been described. Now, in a modified example of the first embodiment, the case of determining using one difference is explained.

For example, as shown in FIG. 22, when a difference waveform (B-A) is obtained in the first difference calculation by subtracting a measured waveform A from a measured waveform B, it turns out that an upward convex peak exists in the difference waveform (B-A). Therefore, in a modified example of the first embodiment, the determination unit 64 determines, in the determining step (S120), the measured waveform A to be the background waveform G.

Thus, when an upward convex peak exists in a calculated difference waveform by only once performing calculation for obtaining the difference waveform, it is acceptable, based on the difference waveform calculated once, to use the measured waveform A, which is to be subtracted from the measured waveform B, to determine the background waveform G.

In contrast, for example, when a difference waveform (A-B) is obtained in the first difference calculation by subtracting a measured waveform B from a measured waveform A as shown in FIG. 21, in the case where no upward convex peak exists in the difference waveform (A-B), the determination unit 64 according to the modified example of the first embodiment determines, in the determining step (S120), the measured waveform A to be the background waveform G.

Thus, when no upward convex peak exists in a calculated difference waveform by only once performing calculation for obtaining the difference waveform, it is acceptable, based on the difference waveform calculated once, to use the measured waveform A, from which the measured waveform B is subtracted, to determine the background waveform G.

Although the case where an alignment mark (line pattern) appears as an upward convex peak in a measured waveform has been described above, it is not limited thereto. The background waveform acquisition method and the mark position detection method described in the above embodiments can also be applied to the case where an alignment mark (line pattern) appears as a downward convex peak in a measured waveform. In that case, “upward convex peak” needs to be read as “downward convex peak” to be applied. The line patterns 16 and 18 of the alignment mark 14 may be formed by a dot, dashed line, segment or the like besides by a consecutive line. Furthermore, if the substrate has conditions, such as the gradient in the same state as that previously used, the background waveform G having been acquired for the previous substrate may also be used.

Functions of processing described in each embodiment may be executed by a computer. A program for causing a computer to implement such functions of processing may be stored in a non-transitory tangible computer-readable storage medium such as a magnetic disk drive.

While the apparatus configuration, control method, and the like not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

Furthermore, any background waveform acquisition method, mark position detection method, electron beam writing method, and electron beam writing apparatus that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A background waveform acquisition method comprising:
scanning a target object with an electron beam, at a plurality of regions which are in a vicinity of a line pattern on the target object where a mark using the line pattern is formed, and are arranged in a direction not parallel to an extending direction of the line pattern; and
determining a waveform of a background which is not the mark, in a plurality of measured waveforms measured by the scanning at the plurality of regions, and outputting the waveform of the background.

2. The method according to claim 1 further comprising:
calculating, for each combination being at least one combination obtained by combining two measured waveforms as a first measured waveform and a second measured waveform, in the plurality of measured waveforms acquired from the plurality of regions, a first difference by subtracting the second measured waveform from the first measured waveform, and a second difference by subtracting the first measured waveform from the second measured waveform of a combination concerned, wherein
the waveform of the background is determined based on a waveform of the first difference and a waveform of the second difference.

3. The method according to claim 1 further comprising:
calculating, for each combination being at least one combination obtained by combining two measured waveforms as a first measured waveform and a second measured waveform, in the plurality of measured waveforms acquired from the plurality of regions, a first difference by subtracting the second measured waveform from the first measured waveform of a combination concerned, wherein
the waveform of the background is determined based on a waveform of the first difference.

4. The method according to claim 1 further comprising:
calculating a parameter using a difference between a template waveform for determining the waveform of the background and a measured waveform concerned, for each measured waveform in the plurality of measured waveforms acquired from the plurality of regions, wherein.
a measured waveform which makes the parameter smaller is determined as the waveform of the background.

5. The method according to claim 1, wherein
the plurality of regions include two regions arranged on both sides of the line pattern to be across from each other.

6. The method according to claim 1, wherein
multiple electron beams are used as the electron beam, and
scanning is performed over each region of the plurality of regions by moving a beam array of “ON” beams in the multiple electron beams, in a scanning direction in order.

7. The method according to claim 1, wherein the line pattern is formed to be concave.

8. A mark position detection method comprising:
scanning a target object with an electron beam, at a plurality of regions which are in a vicinity of a line pattern on the target object where a mark using the line pattern is formed, and are arranged in a direction not parallel to an extending direction of the line pattern;
determining a waveform of a background which is not the mark, in a plurality of measured waveforms measured by the scanning at the plurality of regions;
scanning the target object with an electron beam, at a region including the line pattern;
removing the waveform of the background which has been obtained by the determining, from a measured waveform measured by the scanning the region including the line pattern; and
calculating a mark position based on the measured waveform from which the waveform of the background has been removed, and outputting the mark position.

9. An electron beam writing method comprising:
scanning, for each mark of a plurality of marks on a target object where the plurality of marks using line patterns are formed, the target object with an electron beam, at a plurality of regions each of which is in a vicinity of one of the line patterns, and each of which is arranged in a direction not parallel to an extending direction of the one of the line patterns;
determining, for each of the marks, a waveform of a background which is not a mark concerned, in a plurality of measured waveforms measured by the scanning at the plurality of regions;
scanning, for each of the marks, the target object with an electron beam, at a region including one of the line patterns;
removing, for each of the marks, the waveform of the background which has been obtained by the determining, from a measured waveform measured by the scanning the region including the one of the line patterns;
calculating, for each of the marks, a mark position based on the measured waveform from which the waveform of the background has been removed;
correcting a position of a pattern to be written, using calculated positions of the plurality of marks; and
writing the pattern whose position has been corrected on the target object using an electron beam.

10. An electron beam writing apparatus comprising:
a stage configured to place thereon a target object where a plurality of marks using line patterns are formed;
a scanning mechanism configured to scan, for each mark of the plurality of marks on the target object, the target object with an electron beam, at a plurality of regions each of which is in a vicinity of one of the line patterns, and each of which is arranged in a direction not parallel to an extending direction of the one of the line patterns;
a determination circuit configured to determine, for each of the marks, a waveform of a background which is not a mark concerned, in a plurality of measured waveforms measured by scanning at the plurality of regions;
a background waveform removal circuit configured to remove, for each of the marks, the waveform of the background which has been obtained by determination, from a measured waveform measured by scanning the target object with an electron beam at a region including one of the line patterns;
a mark position calculation circuit configured to calculate, for each of the marks, a mark position based on the measured waveform from which the waveform of the background has been removed;
a correction circuit configured to correct a position of a pattern to be written, using calculated positions of the plurality of marks; and
a writing mechanism configured to include the stage and the scanning mechanism, and to write the pattern whose position has been corrected on the target object using an electron beam.
